(19) United States
(12) Patent Application Publication
(10) Pub. No.: US 2026/0093170 A1
(43) Pub. Date: Apr. 2, 2026

(54) METHOD FOR PATTERNING SUBSTRATE USING METAL OXIDE RESIST

(71) Applicant: Tokyo Electron Limited, Tokyo (JP)

(72) Inventor: Alec Dorfner, Albany, NY (US)

(21) Appl. No.: 18/903,802

(22) Filed: Oct. 1, 2024

(51) Int. Cl. G03F 1/22; G03F 7/38; H01L 21/027

(52) U.S. Cl. CPC G03F 1/22; G03F 7/38; H10P 76/2041

(57) ABSTRACT

A method includes forming a metal-containing layer over a substrate, forming a metal oxide resist over the metal-containing layer, patterning the metal oxide resist to form a patterned metal oxide resist, forming an intermediate mask layer over the patterned metal oxide resist, and removing a portion of the intermediate mask layer to expose the patterned metal oxide resist. Remaining portions of the intermediate mask layer form a patterned intermediate mask layer. The method further includes selectively removing the patterned metal oxide resist and transferring a pattern of the patterned intermediate mask layer to the metal-containing layer to form a patterned metal-containing layer.

### TECHNICAL FIELD

The present disclosure relates generally to methods for processing a substrate, and, in particular embodiments, to methods for patterning a substrate using a metal oxide resist.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of negative photoresist, unexposed portions of the photoresist may be removed by a developing step using a developer (e.g., solvent or gas-phase developer), forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method includes forming a metal-containing layer over a substrate, forming a metal oxide resist over the metal-containing layer, patterning the metal oxide resist to form a patterned metal oxide resist, forming an intermediate mask layer over the patterned metal oxide resist, and removing a portion of the intermediate mask layer to expose the patterned metal oxide resist. Remaining portions of the intermediate mask layer form a patterned intermediate mask layer. The method further includes selectively removing the patterned metal oxide resist and transferring a pattern of the patterned intermediate mask layer to the metal-containing layer to form a patterned metal-containing layer.

In accordance with another embodiment of the present disclosure, a method includes depositing a metal-containing layer over a substrate, depositing a metal oxide resist over the metal-containing layer, and patterning the metal oxide resist to form a patterned metal oxide resist. The patterned metal oxide resist includes a plurality of openings. The method further includes depositing an intermediate mask layer over the patterned metal oxide resist. The intermediate mask layer overfills the plurality of openings. The method further includes removing a portion of the intermediate mask layer to expose a top surface of the patterned metal oxide resist. Remaining portions of the intermediate mask layer form a patterned intermediate mask layer. The method further includes performing an etch process to selectively remove the patterned metal oxide resist and portions of the metal-containing layer not protected by the patterned intermediate mask layer. Remaining portions of the metal-containing layer form a patterned metal-containing layer.

In accordance with yet another embodiment of the present disclosure, a method includes receiving a substrate. The substrate includes a target layer, a metal-containing layer overlying the target layer, and a patterned metal oxide resist overlying the metal-containing layer. The method further includes depositing an intermediate mask layer over the patterned metal oxide resist. A top surface of the intermediate mask layer is above a top surface of the patterned metal oxide resist. The method further includes etching back the intermediate mask layer to expose the patterned metal oxide resist. Remaining portions of the intermediate mask layer form a patterned intermediate mask layer. The method further includes performing a first etch process to selectively remove the patterned metal oxide resist and performing a second etch process to selectively remove portions of the metal-containing layer not protected by the patterned intermediate mask layer. Remaining portions of the metal-containing layer form a patterned metal-containing layer. The method further includes transferring a pattern of the patterned metal-containing layer to the target layer.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1G illustrate cross-sectional views of intermediate stages in the manufacturing of a semiconductor structure in accordance with various embodiments; and

FIG. 2 illustrates a flow diagram of a method for forming a semiconductor structure in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In an embodiment, a method includes forming a metal-containing layer over a substrate, followed by depositing a metal oxide resist layer. The metal oxide resist layer is patterned to create openings, after which an intermediate mask layer is formed, overfilling these openings. A portion of the intermediate mask layer is then removed to expose the patterned metal oxide resist, creating a patterned intermediate mask layer. The method proceeds with selectively removing the patterned metal oxide resist layer and transferring a pattern of the patterned intermediate mask layer to the metal-containing layer, resulting in a patterned metal-containing layer.

This approach offers several advantages in semiconductor device fabrication. In various embodiments, the method allows for the use of a metal-containing underlayer, such as titanium, which may reduce a dose-to-size ratio for patterned features of a metal oxide resist mask and improve throughput for extreme ultraviolet (EUV) scanners. However, selectively etching such metal-containing underlayers with the metal oxide resist mask can be difficult, as both materials may be etched by similar etchants like chlorine-based plasmas, for example. Various embodiments address this challenge by introducing a third material, such as silicon dioxide, as an intermediate mask. This additional layer enables selective etching of the metal-containing underlayer while preserving the benefits of the metal-containing underlayer for lithography. By using the intermediate mask as an etch mask, the process may circumvent the selectivity challenges between the metal oxide resist mask and the metal-containing underlayer, providing a pathway for integrating metal oxide resists with metal-containing underlayers in advanced lithography techniques.

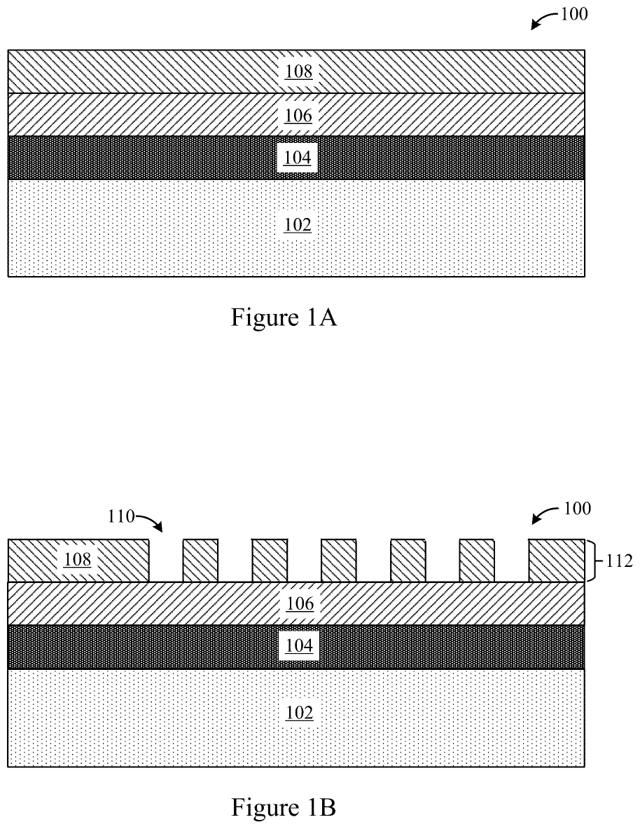

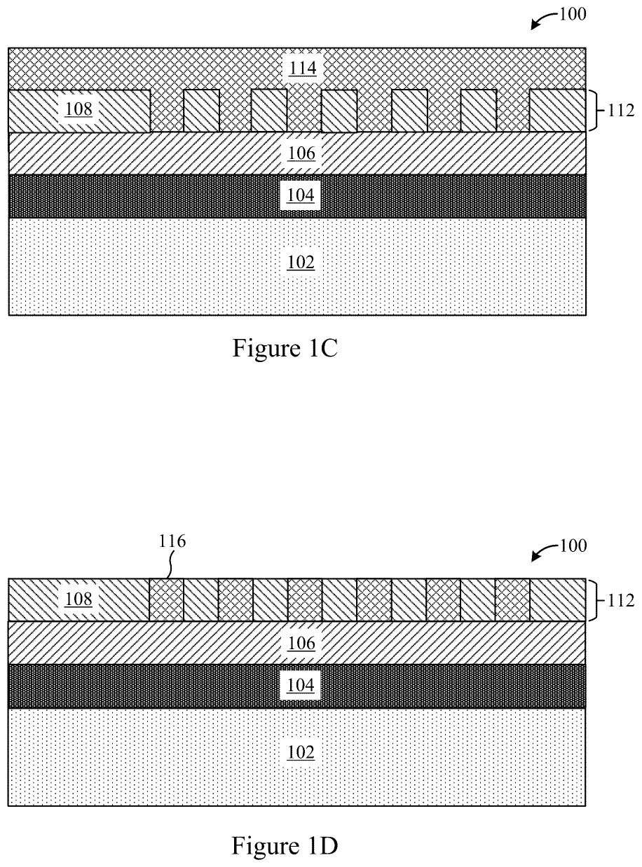

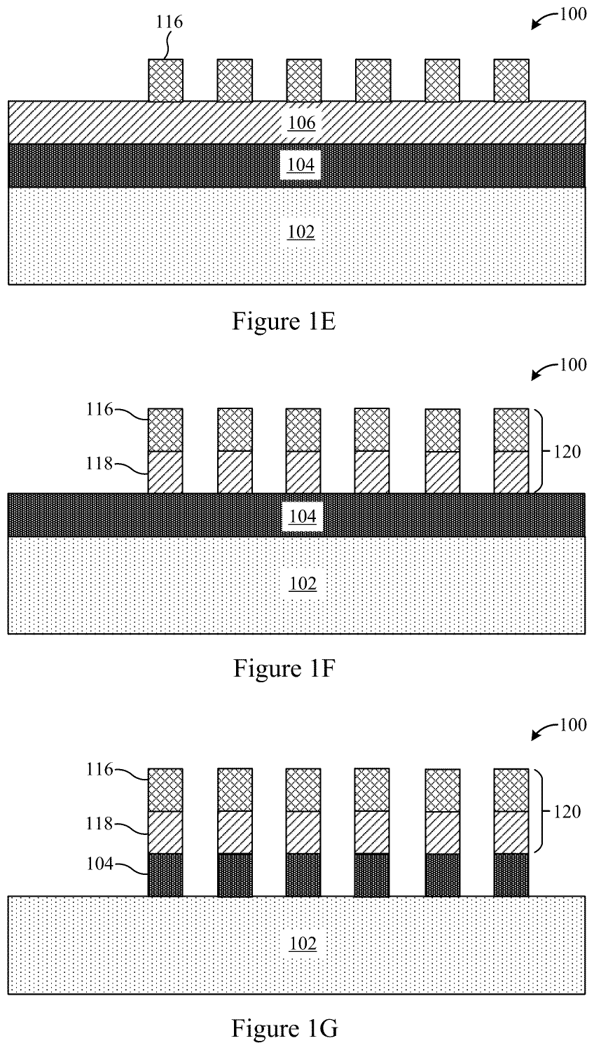

FIGS. 1A-1G illustrate cross-sectional views of intermediate stages in the manufacturing of a semiconductor structure 100 in accordance with various embodiments. In FIG. 1A, the process starts with providing a substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate.

In some embodiments, the substrate 102 may further include semiconductor devices or semiconductor structures and may be formed in any suitable manner, including using any suitable combination of wet and/or dry deposition and etch techniques. In such embodiments, the substrate may include isolation regions such as shallow trench isolation (STI) regions, diffusion regions, as well as other regions formed therein.

In some embodiments, a target layer 104 is formed over the substrate 102. The target layer 104 represents a layer that will be subsequently patterned. In one or more embodiments, the target layer 104 may comprise materials such as silicon, silicon oxynitride, organic materials, non-organic materials, spin-on carbon, amorphous carbon, a combination thereof, or the like. In an embodiment, the target layer 104 may be a silicon bottom anti-reflective coating (Si-BARC), which can enhance the precision of subsequent patterning steps. The target layer 104 may also serve as a mask layer, comprising either a single hard mask or a stacked hard mask. In the case of a stacked hard mask, it may consist of two or more layers of different materials. For instance, in a two-layer configuration, the first layer might comprise a metal-based material such as titanium nitride, titanium, tantalum nitride, tantalum, tungsten-based compounds, ruthenium-based compounds, or aluminum-based compounds. The second layer, in contrast, might be a dielectric layer composed of materials like silicon dioxide, silicon nitride, silicon oxynitride, silicon carbide, amorphous silicon, or polycrystalline silicon.

The deposition of the target layer 104 may be achieved through various suitable processes. In some embodiments, the target layer 104 may be deposited using spin-on coating techniques, chemical vapor deposition (CVD), atomic layer deposition (ALD), plasma-enhanced CVD (PECVD), plasma-enhanced ALD (PEALD), a combination thereof, or the like. The choice of deposition method depends on factors such as the desired thickness, uniformity, and material properties of the target layer 104.

In some embodiments, a metal-containing layer 106 is formed over the target layer 104. In various embodiments, the metal-containing layer 106 may comprise titanium-containing materials, hafnium-containing materials, aluminum-containing materials, zirconium-containing materials, or the like. Titanium-containing materials may include elemental titanium, titanium nitride, titanium oxide, or the like. Hafnium-containing materials may include elemental hafnium, hafnium nitride, hafnium oxide, or the like. Aluminum-containing materials may include elemental aluminum, aluminum nitride, aluminum oxide, or the like. Zirconium-containing materials may include elemental zirconium, zirconium nitride, zirconium oxide, or the like. The metal-containing layer 106 may serve as an intermediate layer for pattern transfer.

The deposition of the metal-containing layer 106 can be accomplished through various methods. In some embodiment, physical vapor deposition (PVD), CVD, ALD, spin-on deposition techniques, a combination thereof, or the like may be employed. The choice of deposition method depends on factors such as the desired thickness, uniformity, and material properties of the metal-containing layer 106. In some embodiments, the metal-containing layer 106 may have a thickness in a range from 1 nm to 20 nm.

In some embodiments, a photoresist layer such as a metal oxide resist layer 108 is formed over the metal-containing layer 106. In an embodiment, the metal oxide resist layer 108 may comprise a tin-containing material such as tin oxide. As described below in greater detail, the metal oxide resist layer 108 will be patterned in subsequent steps to define the desired features.

The deposition of the metal oxide resist layer 108 can be accomplished through various methods. In some embodiment, the metal oxide resist layer 108 may be deposited using CVD, ALD, spin-on deposition techniques, a combination thereof, or the like. The choice of deposition method depends on factors such as the desired thickness, uniformity, and material properties of the metal oxide resist layer 108. In some embodiments, the metal oxide resist layer 108 may have a thickness in a range from 5 nm to 25 nm.

In FIG. 1B, the metal oxide resist layer 108 is patterned to form a patterned metal oxide resist layer 112. The patterning process may form a plurality of openings 110 within the metal oxide resist layer 108. In some embodiments, after the deposition, the metal oxide resist layer 108 may undergo a soft bake process. The soft bake process may be also referred to as a post-deposition bake process.

Subsequently, a photomask that includes a desired pattern is placed over the metal oxide resist layer 108. Once placed, the metal oxide resist layer 108 is exposed to a specific type of radiation through the photomask. In various embodiments, the radiation may include ultraviolet (UV) light, deep ultraviolet (DUV) light, extreme ultraviolet (EUV) light, electron beam, or the like. The radiation causes a chemical change in the exposed areas of the metal oxide resist layer 108. In an embodiment when the metal oxide resist layer 108 comprises a tin-containing material, the metal oxide resist layer 108 may be exposed to EUV light.

In some embodiments, a post-exposure bake may be performed to activate the chemical changes initiated by the exposure. The metal oxide resist layer 108 is then subjected to a development process. Depending on whether the metal oxide resist layer 108 is a positive or negative photoresist, the exposed areas become either soluble (for positive photoresist) or insoluble (for negative photoresist) and are selectively removed by the developer solution. In some embodiments, a hard bake may be performed to harden the remaining portion of the metal oxide resist layer 108.

In other embodiments, the development process may be a gas-phase development process. Depending on whether the metal oxide resist layer 108 is a positive or negative photoresist, the exposed areas become either reactive (for positive photoresist) or inert (for negative photoresist) to a developer gas and are volatized and removed. In some embodiments, when the metal oxide resist layer 108 is a negative photoresist, the developer gas may comprise a hydrogen-containing gas, a halogen-containing gas, a mixture thereof, or the like.

The result of this photolithography process is the patterned metal oxide resist layer 112 with openings 110. The openings 110 define the areas where subsequent etching or material deposition will occur, effectively creating a mask that will be used to transfer the pattern to the underlying layers. In various embodiments, the width and spacing of the openings 110 may be adjusted to achieve different pattern densities and feature sizes. In some embodiments, the patterned metal oxide resist layer 112 may serve as a sacrificial layer in the subsequent steps of the fabrication process. The patterned metal oxide resist layer 112 protects certain areas of the underlying metal-containing layer 106 while exposing others, thus enabling selective etching or deposition in the following stages of the patterning process.

In FIG. 1C, an intermediate mask layer 114 is blanket deposited over the semiconductor structure 100, covering the patterned metal oxide resist layer 112 and filling the openings 110. In various embodiments, the intermediate mask layer 114 may comprise materials such as CVD or ALD silicon oxide, spin-on-glass, spin-on-carbon, or the like. The choice of material for the intermediate mask layer 114 depends on factors such as its compatibility with the underlying layers and its etch selectivity relative to the patterned metal oxide resist layer 112 and the metal-containing layer 106.

In one or more embodiments, the intermediate mask layer 114 layer is deposited in such a way that it completely fills the openings 110 in the patterned metal oxide resist layer 112 and forms a substantially planar surface over the semiconductor structure 100. A thickness of the intermediate mask layer 114 may be controlled to ensure complete filling of the openings while minimizing excess material above the patterned metal oxide resist layer 112, such that a top surface of the intermediate mask layer 114 is above a top surface of the patterned metal oxide resist layer 112. In some embodiments, the intermediate mask layer 114 may have a thickness in a range from 5 nm to 50 nm.

In some embodiments, the intermediate mask layer 114 may enable selective etching of the metal-containing layer 106. By using the intermediate mask layer 114, the patterning process may circumvent the selectivity challenges between the patterned metal oxide resist layer 112 and the metal-containing layer 106. Furthermore, the intermediate mask layer 114 may be used to create a negative image of the original pattern defined by the patterned metal oxide resist layer 112. By filling the openings 110, the intermediate mask layer 114 creates raised areas where the original pattern had openings, and maintains lower areas where the original pattern had photoresist material. Accordingly, the intermediate mask layer 114 may be also referred to as a pattern reversal layer.

In FIG. 1D, the intermediate mask layer 114 (see FIG. 1C) is partially removed to form a patterned intermediate mask layer 116. In various embodiments, the removal process may be performed to selectively remove portions of the intermediate mask layer 114, exposing the top surface of the patterned metal oxide resist layer 112 while leaving the material of the intermediate mask layer 114 in the openings 110 substantially intact. The removal process may include an etch-back process (e.g., reactive ion etching), chemical mechanical polishing (CMP), a combination thereof, or the like. This process effectively creates a new pattern that is the inverse of the original pattern of the patterned metal oxide resist layer 112. The patterned intermediate mask layer 116 now fills the spaces that were originally the openings 110 (see FIG. 1B) in the patterned metal oxide resist layer 112, while the areas above the patterned metal oxide resist layer 112 are now exposed. In the subsequent steps of the patterning process, this newly created pattern will be used to guide the etching of the metal-containing layer 106 and ultimately transfer the desired pattern to the target layer 104.

In FIG. 1E, the patterned metal oxide resist layer 112 (see FIG. 1D) is removed to expose the metal-containing layer 106. The removal process is designed to selectively remove the patterned metal oxide resist layer 112 while leaving the patterned intermediate mask layer 116 intact. After the removal step the original pattern is eliminated, leaving behind the inverse pattern formed by the patterned intermediate mask layer 116. In some embodiments, the removal process may comprise a selective etching process, such as a dry etching process or a wet etching process.

In some embodiments, when the patterned metal oxide resist layer 112 (see FIG. 1D) comprises a tin-containing material, the removal process may include a first halogen-based plasma etch process, a hydrogen-containing plasma etch process, a combination thereof, or the like. The first halogen-based plasma etch process may be performed using chlorine-containing plasma, bromine-containing plasma, or a combination thereof as an etchant. The chlorine-containing plasma may comprise Cl₂ plasma or the like. The bromine-containing plasma may comprise Br₂ plasma or the like. The hydrogen-containing plasma etch process may be performed by a hydrogen-containing plasma, such as H₂ plasma or the like. In other embodiments, when the patterned metal oxide resist layer 112 comprises a tin-containing material, the removal process may include a wet etch process performed using an etchant comprising organic acids such as acetic acid mixed with propylene glycol methyl ether acetate (PGMEA), or the like.

In FIG. 1F, the metal-containing layer 106 (see FIG. 1E) is patterned to form a patterned metal-containing layer 118, such that the pattern of the patterned intermediate mask layer 116 is transferred to the patterned metal-containing layer 118. In various embodiments, the patterning of the metal-containing layer 106 to form the patterned metal-containing layer 118 may be achieved through a dry etching process. The dry etching process selectively removes portions of the metal-containing layer 106 that are not protected by the patterned intermediate mask layer 116, while leaving the protected portions substantially intact. In some embodiments, the patterned intermediate mask layer 116 and the patterned metal-containing layer 118 serve as a hard mask 120 for subsequent processing steps.

In some embodiments when the metal-containing layer 106 comprises a titanium-containing material, the dry etch process may include a second halogen-based plasma etch process or the like. The second halogen-based plasma etch process may be performed using chlorine-containing plasma, bromine-containing plasma, or a combination thereof as an etchant. The chlorine-containing plasma may comprise Cl₂ plasma or the like. The bromine-containing plasma may comprise Br₂ plasma or the like. In some embodiments, the first halogen-based plasma etch process (see FIG. 1E) and the second halogen-based plasma etch process may be performed using different process parameters such as a process pressure and/or a process temperature.

In other embodiments, the first halogen-based plasma etch process (see FIG. 1E) and the second halogen-based plasma etch process may be performed using same process parameters. In such embodiments, after removing the patterned metal oxide resist layer 112 (see FIG. 1D) as described above with reference to FIG. 1E, the first halogen-based plasma etch process may be continued to pattern the metal-containing layer 106 to form the patterned metal-containing layer 118.

In FIG. 1G, the hard mask 120 comprising the patterned intermediate mask layer 116 and the patterned metal-containing layer 118 is used to transfer a pattern of the hard mask 120 to the target layer 104. The transfer process may comprise a suitable etch process while using the hard mask 120 as an etch mask. The suitable etch process may be a dry etch process (e.g. RIE), a wet etch process, a combination thereof, or the like.

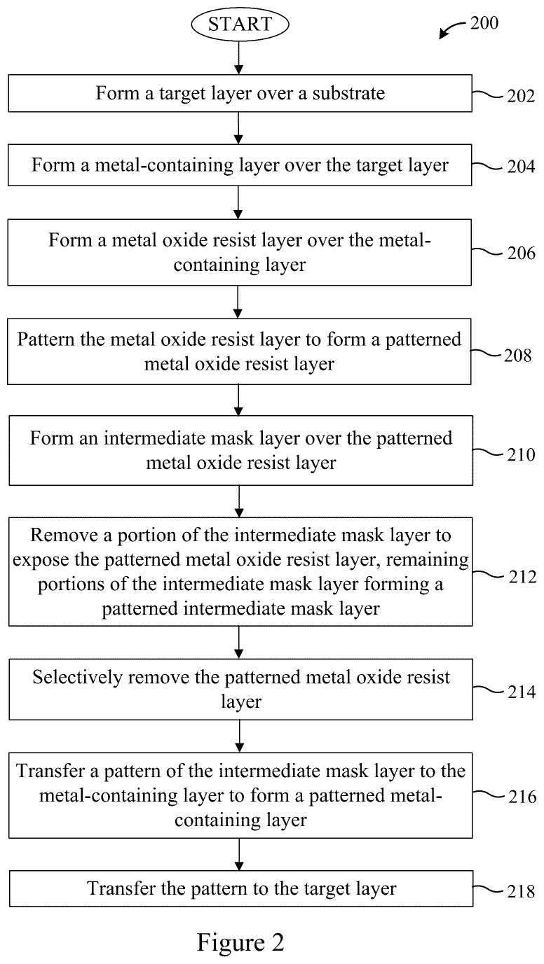

FIG. 2 illustrates a flow diagram of a method 200 for forming a semiconductor structure in accordance with various embodiments. The method 200 is described in conjunction with FIGS. 1A-1G. The method 200 starts with step 202. In step 202, a target layer 104 is formed over a substrate 102, as described above with reference to FIG. 1A. In step 204, a metal-containing layer 106 is formed over the target layer 104, as described above with reference to FIG. 1A. In step 206, a metal oxide resist layer 108 is formed over the metal-containing layer 106, as described above with reference to FIG. 1A.

In step 208, the metal oxide resist layer 108 is patterned to form a patterned metal oxide resist layer 112, as described above with reference to FIG. 1B. In step 210, an intermediate mask layer 114 is formed over the patterned metal oxide resist layer 112, as described above with reference to FIG. 1C. In step 212, a portion of the intermediate mask layer 114 is removed to expose the patterned metal oxide resist layer 112, with remaining portions of the intermediate mask layer 114 forming a patterned intermediate mask layer 116, as described above with reference to FIG. 1D.

In step 214, the patterned metal oxide resist layer 112 is selectively removed, as described above with reference to FIG. 1E. In step 216, a pattern of the patterned intermediate mask layer 116 is transferred to the metal-containing layer 106 to form a patterned metal-containing layer 118, as described above with reference to FIG. 1F. In some embodiments, steps 214 and 216 may be performed through a single process. In such embodiments, the selective removal of the patterned metal oxide resist layer 112 and the patterning of the metal-containing layer 106 occur in one continuous etch step, such as a plasma etch step. In other embodiments, steps 214 and 216 may be performed through separate and different processes. In step 218, the pattern of the patterned intermediate mask layer 116 is transferred to the target layer 104, as described above with reference to FIG. 1G.

Example embodiments of the disclosure are described below. Other embodiments can also be understood from the entirety of the specification as well as the claims filed herein.

Example 1. A method including forming a metal-containing layer over a substrate, forming a metal oxide resist over the metal-containing layer, patterning the metal oxide resist to form a patterned metal oxide resist, forming an intermediate mask layer over the patterned metal oxide resist, and removing a portion of the intermediate mask layer to expose the patterned metal oxide resist. Remaining portions of the intermediate mask layer form a patterned intermediate mask layer. The method further includes selectively removing the patterned metal oxide resist and transferring a pattern of the patterned intermediate mask layer to the metal-containing layer to form a patterned metal-containing layer.

Example 2. The method of example 1, where selectively removing the patterned metal oxide resist includes performing an etch process using chlorine-containing plasma as an etchant.

Example 3. The method of one of examples 1 and 2, where transferring the pattern of the patterned intermediate mask layer to the metal-containing layer includes performing an etch process using chlorine-containing plasma as an etchant.

Example 4. The method of one of examples 1 to 3, where the metal oxide resist includes tin-containing material.

Example 5. The method of one of examples 1 to 4, where the metal-containing layer includes titanium-containing material, hafnium-containing material, aluminum-containing material, or zirconium-containing material.

Example 6. The method of one of examples 1 to 5, where the intermediate mask layer includes a chemical vapor deposition silicon oxide, an atomic layer deposition silicon oxide, spin-on-glass, or spin-on-carbon.

Example 7. The method of one of examples 1 to 6, where selectively removing the patterned metal oxide resist includes performing a wet etch process.

Example 8. A method including depositing a metal-containing layer over a substrate, depositing a metal oxide resist over the metal-containing layer, and patterning the metal oxide resist to form a patterned metal oxide resist. The patterned metal oxide resist includes a plurality of openings. The method further includes depositing an intermediate mask layer over the patterned metal oxide resist. The intermediate mask layer overfills the plurality of openings. The method further includes removing a portion of the intermediate mask layer to expose a top surface of the patterned metal oxide resist. Remaining portions of the intermediate mask layer form a patterned intermediate mask layer. The method further includes performing an etch process to selectively remove the patterned metal oxide resist and portions of the metal-containing layer not protected by the patterned intermediate mask layer. Remaining portions of the metal-containing layer form a patterned metal-containing layer.

Example 9. The method of example 8, where removing the portion of the intermediate mask layer includes performing an etch-back process.

Example 10. The method of one of examples 8 and 9, where the metal-containing layer includes titanium, titanium nitride, titanium oxide, hafnium, hafnium nitride, hafnium oxide, aluminum, aluminum nitride, aluminum oxide, zirconium nitride, or zirconium oxide.

Example 11. The method of one of examples 8 to 10, where the metal oxide resist includes tin oxide.

Example 12. The method of one of examples 8 to 11, where the intermediate mask layer includes a chemical vapor deposition silicon oxide, an atomic layer deposition silicon oxide, spin-on-glass, or spin-on-carbon.

Example 13. The method of one of examples 8 to 12, where the etch process uses chlorine-containing plasma as an etchant.

Example 14. The method of one of examples 8 to 13, further including: before depositing the metal-containing layer over the substrate, depositing a target layer over the substrate, and after performing the etch process, transferring a pattern of the patterned metal-containing layer to the target layer.

Example 15. A method including receiving a substrate. The substrate includes a target layer, a metal-containing layer overlying the target layer, and a patterned metal oxide resist overlying the metal-containing layer. The method further includes depositing an intermediate mask layer over the patterned metal oxide resist. A top surface of the intermediate mask layer is above a top surface of the patterned metal oxide resist. The method further includes etching back the intermediate mask layer to expose the patterned metal oxide resist. Remaining portions of the intermediate mask layer form a patterned intermediate mask layer. The method further includes performing a first etch process to selectively remove the patterned metal oxide resist and performing a second etch process to selectively remove portions of the metal-containing layer not protected by the patterned intermediate mask layer. Remaining portions of the metal-containing layer form a patterned metal-containing layer. The method further includes transferring a pattern of the patterned metal-containing layer to the target layer.

Example 16. The method of example 15, where the first etch process is different from the second etch process.

Example 17. The method of one of examples 15 and 16, where performing the second etch process comprises continuing the first etch process.

Example 18. The method of one of examples 15 to 17, where the second etch process is performed using chlorine-containing plasma as an etchant.

Example 19. The method of one of examples 15 to 18, where the second etch process is performed using bromine-containing plasma as an etchant.

Example 20. The method of one of examples 15 to 19, where transferring the pattern of the patterned metal-containing layer to the target layer comprises performing a third etch process on the target layer while using the patterned intermediate mask layer and the patterned metal-containing layer as an etch mask.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

1. A method comprising:
receiving a substrate comprising a patterned intermediate mask layer and a patterned metal oxide resist overlying a metal-containing layer;
selectively removing the patterned metal oxide resist; and
transferring a pattern of the patterned intermediate mask layer to the metal-containing layer to form a patterned metal-containing layer.

2. The method of claim 1, wherein selectively removing the patterned metal oxide resist comprises performing an etch process using chlorine-containing plasma as an etchant.

3. The method of claim 1, wherein transferring the pattern of the patterned intermediate mask layer to the metal-containing layer comprises performing an etch process using chlorine-containing plasma as an etchant.

4. The method of claim 1, wherein the patterned metal oxide resist comprises tin-containing material.

5. The method of claim 1, wherein the patterned metal-containing layer comprises titanium-containing material, hafnium-containing material, aluminum-containing material, or zirconium-containing material.

6. The method of claim 1, wherein the patterned intermediate mask layer comprises a chemical vapor deposition silicon oxide, an atomic layer deposition silicon oxide, spin-on-glass, or spin-on-carbon.

7. The method of claim 1, wherein selectively removing the patterned metal oxide resist comprises performing a wet etch process.

8. A method comprising:
receiving a substrate comprising a patterned intermediate mask layer and a patterned metal oxide resist overlying a metal-containing layer; and
performing an etch process to selectively remove the patterned metal oxide resist and portions of the metal-containing layer not protected by the patterned intermediate mask layer, remaining portions of the metal-containing layer forming a patterned metal-containing layer.

9. (canceled)

10. The method of claim 8, wherein the metal-containing layer comprises titanium, titanium nitride, titanium oxide, hafnium, hafnium nitride, hafnium oxide, aluminum, aluminum nitride, aluminum oxide, zirconium nitride, or zirconium oxide.

11. The method of claim 8, wherein the patterned metal oxide resist comprises tin oxide.

12. The method of claim 8, wherein the patterned intermediate mask layer comprises a chemical vapor deposition silicon oxide, an atomic layer deposition silicon oxide, spin-on-glass, or spin-on-carbon.

13. The method of claim 8, wherein the etch process uses chlorine-containing plasma as an etchant.

14. (canceled)

15. A method comprising:
receiving a substrate comprising a target layer, a metal-containing layer overlying the target layer, and a patterned metal oxide resist and a patterned intermediate mask layer overlying the metal-containing layer;
performing a first etch process to selectively remove the patterned metal oxide resist;
performing a second etch process to selectively remove portions of the metal-containing layer not protected by the patterned intermediate mask layer, remaining portions of the metal-containing layer forming a patterned metal-containing layer; and
transferring a pattern of the patterned metal-containing layer to the target layer.

16. The method of claim 15, wherein the first etch process is different from the second etch process.

17. The method of claim 15, wherein performing the second etch process comprises continuing the first etch process.

18. The method of claim 15, wherein the second etch process is performed using chlorine-containing plasma as an etchant.

19. The method of claim 15, wherein the second etch process is performed using bromine-containing plasma as an etchant.

20. The method of claim 15, wherein transferring the pattern of the patterned metal-containing layer to the target layer comprises performing a third etch process on the target layer while using the patterned intermediate mask layer and the patterned metal-containing layer as an etch mask.

21. The method of claim 8, wherein the etch process uses bromine-containing plasma as an etchant.

22. The method of claim 8, wherein:
the substrate further comprises a target layer below the metal-containing layer; and
the method further comprises, after performing the etch process, transferring a pattern of the patterned metal-containing layer to the target layer.
